(19) United States
(12) Patent Application Publication
(10) Pub. No.: US 2009/0066681 A1
(43) Pub. Date: Mar. 12, 2009

(54) DIGITAL-TO-ANALOG CONVERTER INCLUDING A SOURCE DRIVER AND DISPLAY DEVICE AND METHOD FOR DRIVING THE DIGITAL-TO-ANALOG CONVERTER

(76) Inventors: Ah-reum KIM, Seoul (KR); Sun-kyu Son, Suwon-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/163,779

(22) Filed: Jun. 27, 2008

(30) Foreign Application Priority Data
Sep. 12, 2007 (KR) 10-2007-0092538

(51) Int. Cl. G09G 3/00; H03M 1/68

(52) U.S. Cl. 345/210; 341/145

(57) ABSTRACT

Provided are a division-type DAC, a method for driving the division-type DAC, a source driver and a display device having the division-type DAC. A decoder of the DAC is divided into a plurality of decoders, so that the number of transistors of each decoder is reduced and the size of the decoder is reduced. Therefore, the DAC with the reduced size, the method for driving the DAC, the source driver and the display device having the DAC with the reduced size can be provided.

### CROSS-REFERENCE TO RELATED APPLICATION

This application claims priority under 35 U.S.C. §119 to Korean Patent Application No. 10-2007-0092538 filed in the Korean Intellectual Patent Office on Sep. 12, 2007, the contents of which are incorporated by reference in their entirety.

### BACKGROUND

The present disclosure relates to a digital-to-analog converter (DAC), a method for driving the DAC, a source driver and a display device having the DAC, and more particularly, to a division-type digital-to-analog converter (DAC), a method for driving the division-type DAC, and a source driver and a display device having the division-type DAC.

Recently, lighter and slimmer electronic appliances such as monitors, notebook computers, TVs, and mobile communication terminals are in demand. To meet such demands, various flat-panel display devices are rapidly developed and popularized as a replacement for cathode ray tubes (CRTs).

One type of flat-panel display device is a liquid crystal display (LCD). An LCD includes an upper substrate where common electrodes and color filters are formed, a lower substrate where thin film transistors (TFTs) and pixel electrodes are formed, and liquid crystals having dielectric anisotropy injected between the upper and the lower substrates. An electric field is formed when a voltage is applied to the pixel electrode and the common electrode. Light transmittance of the liquid crystal is changed by controlling the intensity of the electric field. The LCD displays an image according to light transmittance varying with the intensity of the electric field.

The LCD receives red/green/blue (RGB) data from an external host system, i.e., a graphic source. A data format of the inputted RGB data is transformed by a time controller (T-Con) of the LCD, and the transformed RGB data is transferred to a source driver. The source driver selects analog gray-scale voltages corresponding to the RGB data and applies the selected analog gray-scale voltages to the LCD panel. In this way, the image display operation of the LCD is performed.

Generally, the number of bits of the RGB data inputted from the graphic source to the time controller must be identical to the number of bits of data that can be processed by the source driver. The currently available LCDs are 18-bit (n=6) products with 6-bit RGB, or 24-bit (3×n=24) products with 8-bit RGB.

In recent years, as the size of electronic appliances such as LCD TV increases, there is a need for a source driver that can process data signal of 10 bits (n=10) or more so as to reproduce more detail and various colors.

However, there are several limitations in increasing data processing specification of the source driver. For example, a digital-to-analog converter (DAC) for converting input pixel data into analog gray-scale voltages is embedded into the source driver. As the number of bits increases, the number of transistors of the DAC is significantly increased. Thus, as the number of bits increases, the chip size of the source driver increases. Likewise, the size of the LCD with the built-in source driver also increases.

### SUMMARY

The present disclosure provides a DAC having a reduced size, a method for driving the DAC, a source driver and a display device having the DAC.

In accordance with an exemplary embodiment, a digital-to-analog converter includes: a first voltage divider including a plurality of resistors; a first decoder configured to receive division voltages from the first voltage divider to output a plurality of gamma reference voltages; a second decoder configured to output two successive voltages among the first gamma reference voltages as second and third gamma reference voltages; a second voltage divider including a plurality of resistors to divide the second and third gamma reference voltages into a plurality of gamma reference voltages; and a third decoder configured to receive the division voltages from the second voltage divider to output a fourth gamma reference voltage.

The first voltage divider may include 2^{L+M} coarse resistors, and the second voltage divider may include 2^{N} fine resistors, where L, M and N are natural numbers.

The first decoder may be configured to receive (L+M+N)-bit pixel data.

The first decoder may include an L-bit decoder, the second decoder may include an M-bit decoder, and the third decoder may include an N-bit decoder.

The second decoder may include two M-bit decoders, and a difference between least significant bits (LSB) of pixel data inputted to the two M-bit decoders may be 1.

The digital-to-analog converter may be an (L+M+N)-bit converter. The values of L, M and N may be 1, 7, and 2, respectively.

In accordance with another exemplary embodiment, a source driver for generating and outputting a gamma reference voltage by using a reference voltage includes: a first voltage divider with a plurality of resistors; a second voltage divider with a plurality of resistors; and first, second, and third decoders configured to select division voltages outputted from the first and the second voltage dividers.

The first decoder may select a first gamma reference voltage based on a division voltage outputted from the first voltage divider. The second decoder may select second and third gamma reference voltages based on the first gamma reference voltage. The third decoder may receive the second and third voltages and select a fourth gamma reference voltage based on a division voltage outputted from the second voltage divider.

The first voltage divider may include 2^{L+M} coarse resistors, and the second voltage divider may include 2^{N} fine resistors, where L, M and N are natural numbers.

The first decoder may be configured to select one of 2^{L} division voltages and output the selected division voltage as a first gamma reference voltage. The second decoder may be configured to output two successive voltages of the first gamma reference voltages as second and third gamma reference voltages. The third decoder may be configured to receive 2^{N} division voltages from the second voltage divider and output one of the 2^{N} division voltages as a fourth gamma reference voltage.

In accordance with yet another exemplary embodiment, a display device includes: a display panel configured to display an image; and a source driver configured to generate and output a gamma reference voltage by using a reference voltage, the source driver including: a first voltage divider with a plurality of resistors; a second voltage divider with a plurality of resistors; and first, second, and third decoders configured to select division voltages outputted from the first and the second voltage dividers.

The first decoder may select a first gamma reference voltage based on a division voltage outputted from the first voltage divider. The second decoder may select second and third gamma reference voltages based on the first gamma reference voltage. The third decoder may receive the second and third voltages and select a fourth gamma reference voltage based on a division voltage outputted from the second voltage divider.

In accordance with still another exemplary embodiment, a method for driving a digital-to-analog converter includes: generating a plurality of division voltages; selecting first gamma reference voltages among the plurality of division voltages; selecting successive second and third gamma reference voltages among the first gamma reference voltages; generating a plurality of division voltages based on the second and third gamma reference voltages; and selecting a fourth gamma reference voltage among the plurality of division voltages.

Selecting the first gamma reference voltages among the plurality of division voltages may include selecting the first gamma reference according to L-bit pixel data of the (L+M+N)-bit pixel data.

Selecting the first gamma reference voltages among the plurality of division voltages may include: selecting one of 2^{L} division voltages divided by L-bit pixel data and outputting the selected division voltage as the first gamma reference voltages.

Selecting the successive second and third gamma reference voltages among the first gamma reference voltages may include: selecting the second gamma reference voltage by using M-bit pixel data of the (L+M+N)-bit pixel data; adding 1 to the M-bit pixel data of the (L+M+N)-bit pixel data; and selecting the third gamma reference voltage by using the value of 1+the M-bit pixel data.

Selecting the fourth gamma reference voltage among the plurality of division voltages may include selecting the fourth gamma reference voltage by using N-bit pixel data of the (L+M+N)-bit pixel data.

### BRIEF DESCRIPTION OF THE DRAWINGS

Exemplary embodiments can be understood in more detail from the following description taken in conjunction with the accompanying drawings, in which:

FIG. 1 is a block diagram of an LCD in accordance with an exemplary embodiment;

FIG. 2 is a block diagram of a source driver in accordance with the exemplary embodiment;

FIGS. 3 and 4 are circuit diagrams of a DAC in accordance with the exemplary embodiment;

FIG. 5 is a block diagram of a pixel data format in accordance with the exemplary embodiment;

FIG. 6 is a flowchart illustrating an operation of the DAC in accordance with the exemplary embodiment; and

FIGS. 7A through 7C are graphs illustrating an operation of the DAC in accordance with the exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as being limited to the embodiments set forth herein. Rather, these embodiments are provided so that this disclosure will be thorough and complete, and will fully convey the scope of the present invention to those skilled in the art. In the figures, like reference numerals refer to like elements throughout.

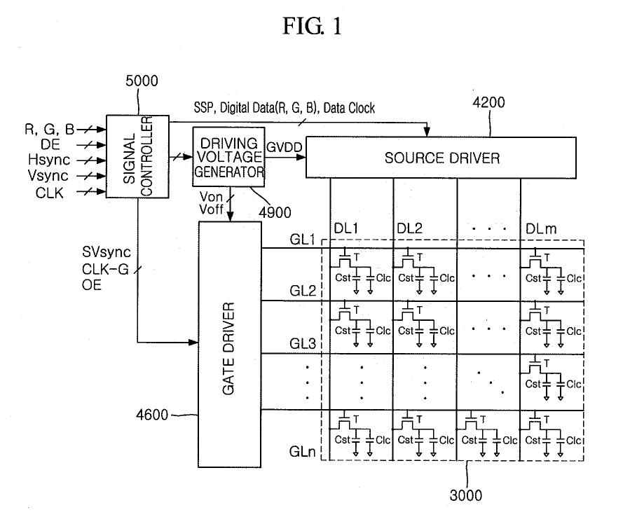

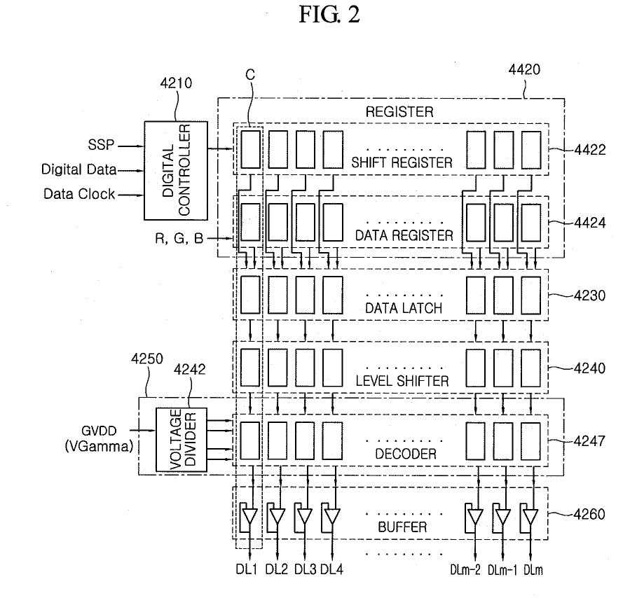

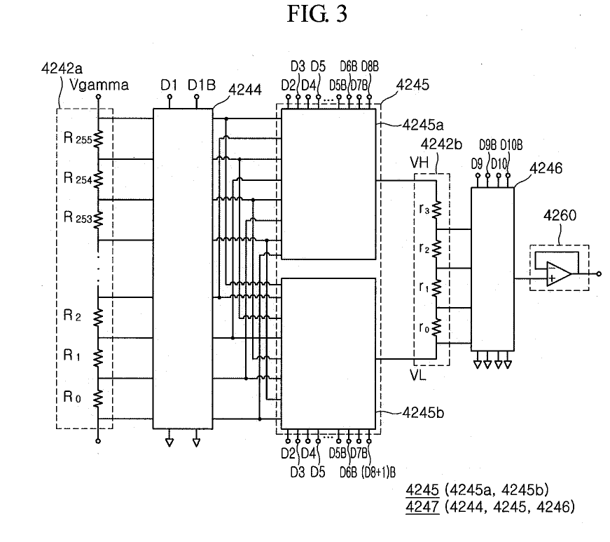

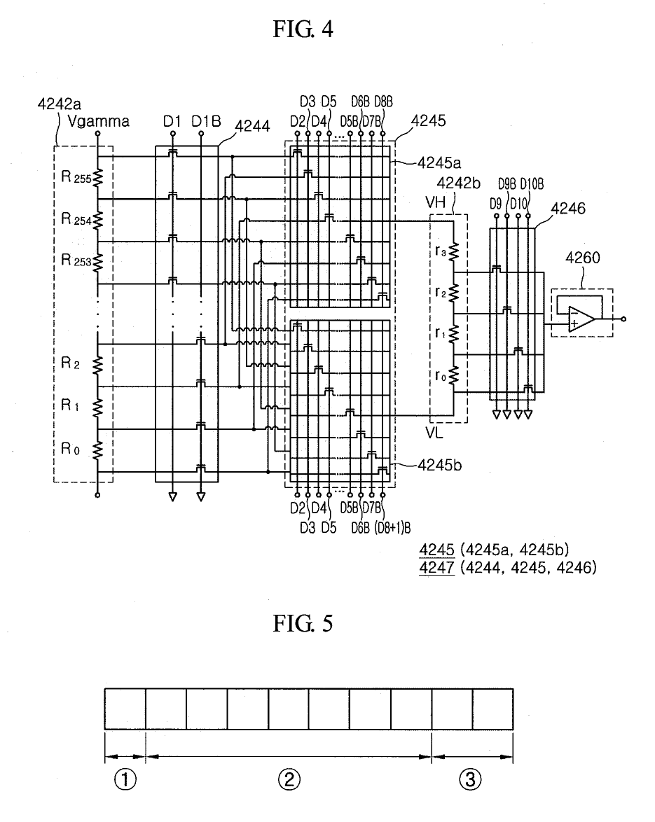

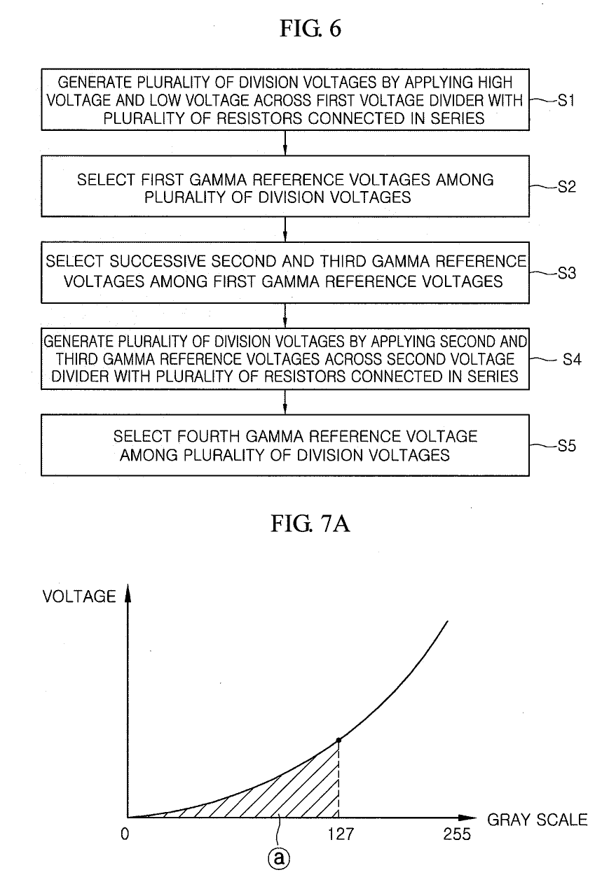

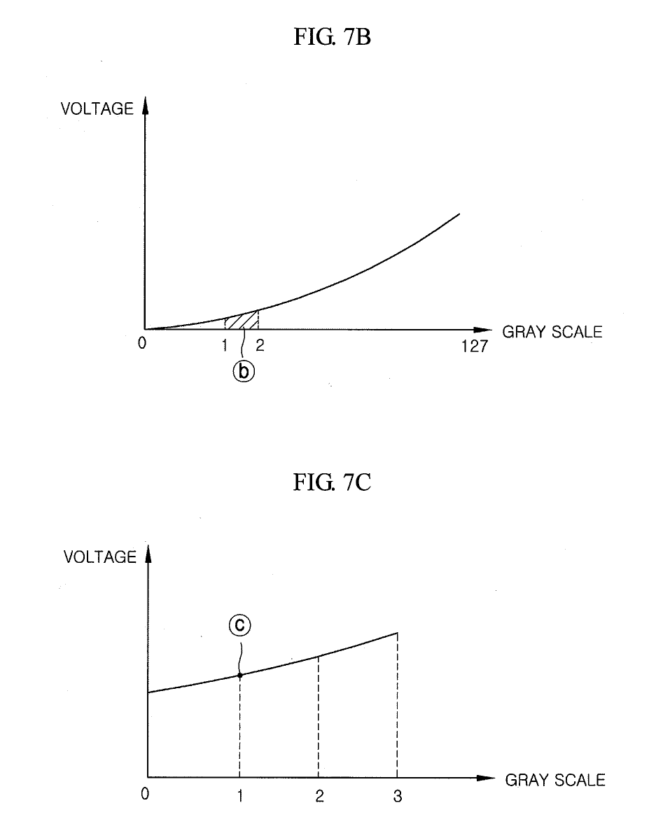

FIG. 1 is a block diagram of an LCD in accordance with an exemplary embodiment. FIG. 2 is a block diagram of a source driver in accordance with the exemplary embodiment. FIGS. 3 and 4 are circuit diagrams of a DAC in accordance with the exemplary embodiment. FIG. 5 is a block diagram of a pixel data format in accordance with the exemplary embodiment. FIG. 6 is a flowchart illustrating an operation of the DAC in accordance with the exemplary embodiment. FIGS. 7A through 7C are graphs illustrating an operation of the DAC in accordance with the exemplary embodiment.

Referring to FIG. 1, the LCD in accordance with the exemplary embodiment includes an LCD panel 3000 displaying an image, a gate driver 4600, a source driver 4200, a driving voltage generator 4900, and a signal controller 5000.

The LCD panel 3000 includes: a plurality of gate lines GL1-GLn arranged in a substantially row direction; a plurality of data lines DL1-DLm arranged in a column direction substantially perpendicular to the gate lines GL1-GLn; and a plurality of pixels provided at intersections of the gate lines GL1-GLn and the data lines DL1-DLn. The pixels include red R pixels, green G pixels, and blue B pixels, each of which includes a thin film transistor T and a liquid crystal capacitor Clc. A natural color can be reproduced by combination of the RGB pixels. The pixel may further include a storage capacitor Cst. The LCD panel 3000 includes a TFT substrate (not shown), a common electrode substrate (not shown), and a liquid crystal layer (not shown). The TFT substrate includes the TFTs T, the gate lines GL1-GLn, the data lines DL1-DLm, and pixel electrodes for liquid crystal capacitors Clc. The common electrode substrate includes a black matrix, a color filter, and common electrodes for the liquid crystal capacitors Clc. The liquid crystal layer is interposed between the TFT substrate and the common electrode substrate.

The TFTs T have gate terminals connected to the gate lines GL1-GLn, source terminals connected to the data lines DL1-DLm, drain terminals connected to the pixel electrodes of the liquid crystal capacitors Clc, respectively. The TFTs T operate in response to gate turn-on voltages applied through the gate lines GL1-GLn, and supplies data signals (i.e., gray-scale voltages) of the data lines DL1-DLm to the pixel electrodes of the pixel capacitors to thereby change electric fields across the liquid crystal capacitors Clc. Since the changed electric fields change the arrangement of liquid crystals within the LCD panel 3000, the transmittance of light supplied from a backlight can be controlled.

As a domain regulator for regulating the alignment direction of the liquid crystals, a plurality of cutout and/or protrusion patterns may be formed on the pixel electrodes of the liquid crystal capacitors Clc, and a plurality of protrusion and/or cutout patterns may be formed on the common electrodes. In this exemplary embodiment, the liquid crystals are vertically aligned, but the present invention is not limited thereto.

An LCD driver is provided outside the LCD panel 3000. The LCD driver supplies driving signals of the LCD panel 3000. The LCD driver includes the gate driver 4600, the source driver 4200, the driving voltage generator 4900, and the signal controller 5000.

The gate driver 4600 and/or the source driver 4200 may be mounted on the lower substrate of the LCD panel 3000, i.e., the TFT substrate. Alternatively, the gate driver 4600 and/or the source driver 4200 may be separately mounted on a printed circuit board (PCB) and then electrically connected to the LCD panel through a flexible printed circuit board (FPC). In this exemplary embodiment, the gate driver 4600 and the source driver 4200 may be manufactured as at least one driver chip and mounted on the LCD panel. Moreover, the driving voltage generator 4900 and the signal generator 5000 may be mounted on a PCB and electrically connected to the LCD panel 3000 through an FPC.

The signal controller 5000 receives RGB pixel data and input control signals from an external graphic controller (not shown). The input control signals include a vertical sync signal Vsync, a horizontal sync signal Hsync, a main clock CLK, and a data enable signal DE. The signal controller 5000 processes the RGB pixel data according to operating conditions of the LCD panel 3000, generates a gate control signal and a data control signal, and transfers the gate control signal to the gate driver 4600. The pixel data are rearranged according to the pixel arrangement of the LCD panel 3000. The gate control signal includes a vertical sync start signal SVsync for indicating output start of the gate turn-on signal, a gate clock signal CLK-G, and an output enable signal OE. The data control signal includes a horizontal sync start signal, a load signal, an inversion signal, and a data clock signal. The horizontal sync start signal indicates transmission start of the pixel data. The load signal instructs application of a data voltage to a corresponding data line. The inversion signal inverts a polarity of a gray-scale voltage with respect to a common voltage.

The driving voltage generator 4900 generates a variety of driving voltages required for driving the display device, for example, a reference voltage GVDD, a gate turn-on voltage Von, a gate turn-off voltage Voff, and a common voltage using an external voltage from an external power supply. The driving voltage generator 4900 applies the gate turn-on voltage Von and the gate turn-off voltage Voff to the gate driver 4600 and applies the reference voltage GVDD to the source 4200 according to the control signal from the signal controller 5000. The reference voltage GVDD is used as a reference to generate a gray-scale voltage for driving the liquid crystals.

The gate driver 4600 receives the gate turn-on voltage Von and the gate turn-off voltage Voff from the driving voltage generator 4900 and applies them to the gate lines GL1-GLn according to the external control signal. Accordingly, the TFTs T can be controlled so that the gray scale voltages are respectively applied to corresponding pixels.

The source driver 4200 generates the gray-scale voltages using the control signal from the signal controller 5000 and the reference voltage GVDD from the driving voltage generator 4900, and applies the gray-scale voltages to the data lines DL1-DLm. That is, the source driver 4200 converts digital pixel data to analog data signals, i.e., gray-scale voltages, based on the reference voltage GVDD.

Referring to FIG. 2, the source driver 4200 according to the exemplary embodiment includes a digital controller 4210, a register 4420, a data latch 4230, a level shifter 4240, a DAC 4250, and a buffer 4260. The digital controller 4210 controls the register 4420 according to the pixel data and the control signals which are outputted from the signal controller 5000. The register 4420 includes a shift register 4422 configured to sequentially transfer sampling signals according to the pixel data inputted from the digital controller 4210, and a data register 4424 configured to temporarily store the pixel data. The data latch 4230 samples the pixel data in response to the sampling signal and latches the sampled pixel data. The level shifter 4240 shifts the voltage levels of the pixel data to high voltage levels so that the pixel data from the data latch 4230 can be inputted to the DAC 4250. The DAC 4250 converts the level-shifted pixel data into gray-scale voltages. The buffer 4260 supplies the converted pixel data to the data lines DL1-DLm.

The shift register 4422 generates the sampling signal based on the control signal outputted from the digital controller 4210, and supplies the sampling signal to the data latch 4230. The data register 4424 temporarily stores the sequentially inputted RGB pixel data. The data latch 4230 samples the RGB pixel data which are temporarily stored in the data register 4424 in response to the sampling signal outputted from the shift register 4422 and latches the sampled pixel data. The data latch 4230 simultaneously latches and outputs the pixel data corresponding to the data lines DL1-DLm.

The DAC 4250 converts the pixel data from the level shifter 4240 into analog data signals, i.e., gray-scale voltages, and outputs the gray-scale voltages to the buffer 4260. In addition, the DAC 4250 can generate level-based gamma reference signals, and select them according to the level-shifted pixel data outputted from the level shifter 4240. As illustrated in FIGS. 2 through 4, the DAC 4250 may include a voltage divider 4242 and a decoder 4247. In this exemplary embodiment, one of a plurality of channels C and a 10-bit DAC 4250 will be exemplarily described. The 10-bit DAC 4250 is configured to receive 10-bit pixel data as illustrated in FIG. 5.

A reference voltage GVDD is divided by a voltage divider 4242 and outputted as a plurality of gray-scale voltages by a decoder 4247 to change the transmittance of liquid crystals.

The voltage divider 4242 generating the level-based gamma reference voltages includes a first voltage divider 4242a and a second voltage divider 4242b. The first voltage divider 4242a is connected to a first decoder 4244 to generate first level-based gamma reference voltages, and the second divider 4242b is connected to second and third decoders 4245 and 4246 to generate second level-based gamma reference voltages. The first voltage divider 4242a includes a resistor array of a plurality of resistors connected in series between the gamma voltage Vgamma (i.e., the reference voltage GVDD applied from the driving voltage generator 4900) and a ground voltage, and generates the first level-based gamma reference voltages for representing predetermined gray scales through a voltage division of each resistor. The second voltage divider 4242b includes a resistor array of a plurality of resistors connected in series between a second gamma reference voltage and a third gamma reference voltage selected by the second decoder 4245, and generates the second level-based gamma reference voltages for representing predetermined gray scales through a voltage division of each resistor. In this exemplary embodiment, since the 10-bit DAC 4250 is used, the voltage divider 4242 can generate 1024 level-based gamma reference voltages to represent 0-1023 gray scales through a combination of the first voltage divider 4242a and the second voltage divider 4242b. In addition, although not shown, the voltage divider 4242 may include a gamma correction circuit that can correct the gamma reference voltage so as to output the gamma reference voltages according to an ideal gamma curve. Although the voltage divider 4242 is included in the DAC 4250 of the source driver in this exemplary embodiment, it can also be provided separately from the source driver, so that the level-based gamma reference voltages can be applied as external inputs to the DAC 4250. That is, the voltage divider 4242 can be provided inside the DAC 4250 or can be provided outside the source driver.

The first voltage divider 4242a may include a plurality of resistors, i.e., 2^{L+M} resistors connected in series between the gamma voltage Vgamma and the ground voltage. In this exemplary embodiment, the first voltage divider 4242a may include 2¹⁺⁷(=256) resistors, that is, 0^{th} through 255^{th} coarse resistors R₀-R₂₅₅.

The second voltage divider 4242b may include 2^{N} resistors connected in series between two voltages outputted from the second decoder 4245. In this exemplary embodiment, the second voltage divider 4242b may include 2²(=4) resistors, that is, 0^{th} through 3^{rd} fine resistors r₀-r₃.

As described above, the voltage divider 4242 in accordance with the exemplary embodiment can represent a total of 10-bit(=1024) gray scales by using the first voltage divider 4242a representing 2¹⁺⁷(=256) gray scales and the second voltage divider 4242b representing 2²(=4) gray scales.

The decoder 4247 selects the gamma reference voltage corresponding to the pixel data from the voltage divider 4242 and may include first through third decoders 4244, 4245 and 4246. In this exemplary embodiment, the decoder 4247 may include a full-type decoder that receives all the level-based gamma reference voltages and outputs the gamma reference voltage selected according to the input pixel data. Further, each of the first through third decoders 4244, 4245 and 4246 is implemented with a transistor. Each decoder can select the gamma reference voltage corresponding to the pixel data among the level-based gamma reference voltages applied from the voltage divider 4242 by a switching operation of the transistor.

The first decoder 4244 is configured to select the first gamma reference voltages and may include a 2^{L}-bit decoder. In this exemplary embodiment, L is equal to 1, and thus 2¹ bits, i.e., a 1-bit decoder is used as the first decoder 4244. In addition, in order to select the first level-based gamma reference voltages through the division resistors, input terminals of the first decoder 4244 may be connected between the 0^{th} through 255^{th} coarse resistors R₀-R₂₅₅ which are connected in series between the gamma voltage Vgamma of the first voltage divider 4242a and the ground voltage. The first decoder 4244 can select the first level-based gamma reference voltage applied from the first voltage divider 4242a according to the gray scale signal determined according to the pixel data, that is, the pixel data converted by the level shifter 4240. This can be determined according to the most significant bit (MSB) \textcircled{1} of the pixel data. For example, the first decoder 4244 divides the 0^{th} through 255^{th} coarse resistors R₀-R₂₅₅ into two groups: the 0^{th} through 127^{th} coarse resistors R₀-R₁₂₇ and the 128^{th} through 255^{th} coarse resistors R₁₂₈-R₂₅₅. The first divider 4244 selects the 0^{th} through 127^{th} coarse resistors R₀-R₁₂₇ when the MSB \textcircled{1} of the pixel data is 0, and selects the 128^{th} through 255^{th} coarse resistors R₁₂₈-R₂₅₅ when the MSB \textcircled{1} of the pixel data is 1. In this way, the 1-bit decoder can be implemented. Alternatively, the first decoder 4244 can select the 128^{th} through 255^{th} coarse resistors R₁₂₈-R₂₅₅ when the MSB \textcircled{1} of the pixel data is 0, and select the 0^{th} through 127^{th} coarse resistors R₀-R₁₂₇ when the MSB \textcircled{1} of the pixel data is 1. The L-bit may not be the MSB. The L-bit may be a bit located at an arbitrary position of the pixel data. The first decoder 4244 has the input terminals and the output terminals of the same number, which are correspondingly connected to one another. Thus, the first gamma reference voltages outputted from the output terminals of the first decoder 4244 are inputted to the second decoder 4245.

The second decoder 4245 is configured to select the second and third gamma reference voltages and may include a 2^{M}-bit decoder. In this exemplary embodiment, L is equal to 7, and thus 2⁷ bits, i.e., a 7-bit decoder is used as the second decoder 4245. The second decoder 4245 includes two 7-bit decoders. Specifically, the second decoder 4245 may include a first full-type decoder 4245a selecting the second gamma reference voltage, and a second full-type decoder 4245b selecting the third gamma reference voltage. The first gamma reference voltage is equally applied to the first full-type decoder 4245a and the second full-type decoder 4245b. In addition, the second decoder 4245 can select one of the first gamma reference voltages applied from the first decoder 4244 according to the pixel data converted by the level shifter 4240. This can be implemented using the pixel data \textcircled{2} other than two least significant bits (LSBs) \textcircled{3} and the MSB \textcircled{1} of the pixel data. For example, when 10-bit pixel data is used as in this exemplary embodiment, 7-bit pixel data \textcircled{2} other than 2-bit LSB \textcircled{3} and 1-bit MSB \textcircled{1} of the pixel data can be used. In this case, the second decoder 4245 can apply the different second and third gamma reference voltages to the second voltage divider 4242b. To this end, the first full-type decoder 4245a is configured to receive the 7-bit pixel data \textcircled{2} and generate the second gamma reference voltage, and the second full-type decoder 4245b is configured to receive a value made by adding 1 to the pixel data applied to the first full-type decoder 4245a and select the third gamma reference voltage. The present disclosure is not limited to this exemplary embodiment. The second decoder 4245 can select the second and third gamma reference voltages by using M-bit located at an arbitrary position of the pixel data.

The third decoder 4246 is configured to select the fourth gamma reference voltage. The third decoder 4246 may receive the output voltage of the second voltage divider 4242b and select the fourth gamma reference voltage. In this case, the third decoder 4246 may include a 2^{N}-bit decoder. In this exemplary embodiment, N is equal to 2, and thus 2² bits, i.e., a 2-bit decoder is used as the third decoder 4246. The third decoder 4246, the 2-bit decoder, can select one of the output voltages of the second voltage divider 4242b by using 2-bit LSB \textcircled{3} of the 10-bit pixel data. That is, input terminals of the third decoder 4246 are respectively connected between the 0^{th} through 3^{rd} fine resistors r₀-r₃ which are connected in series between the input terminals of the second gamma reference voltage and the third gamma reference voltage outputted from the second voltage divider 4242b. The third decoder 4246 can select the fourth gamma reference voltage, which is a final gamma reference voltage, through a division voltage by selecting one of the 0^{th} through 3^{rd} fine resistors r₀-r₃ according to the pixel data. The present disclosure is not limited to any exemplary embodiment. The third decoder 4246 may select the fourth gamma reference voltage by using N-bit located at an arbitrary position of the pixel data.

The buffer 4260 is configured to supply the analog signal converted by the DAC 4250, i.e., the signal having the same voltage level as the fourth gamma reference voltage, to the source line of the LCD panel at higher driving power. The buffer 4260 may include a unity gain amp.

Although the decoder 4247 is divided into the first decoder 4244 (1-bit decoder), the second decoder 4245 (7-bit decoder), and the third decoder 4246 (2-bit decoder) in this exemplary embodiment, the disclosure is not limited thereto. The DAC 4250 may include first through third decoders 4244, 4245 and 4246 with different bits. That is, the DAC 4250 according to this exemplary embodiment may include three decoders: a 2^{L}-bit decoder, a 2^{M}-bit decoder, and a 2^{-N}-bit decoder. More specifically, the DAC 4250 may include a first voltage divider 4242a, a first decoder 4244, a second decoder 4245, a second voltage divider 4242b, and a third decoder 4246. The first voltage divider 4242a includes 2^{L+M} resistors connected in series, and generates 2^{L+M} first level-based gamma reference voltages. The first decoder 4244 divides the first voltage divider 4242a into 2^{L} in response to an L-bit digital signal, and selects an output voltage of one of the 2^{L}-divided first voltage dividers. The second divider 4245 selects and outputs two successive voltages VH and VL of the output voltages of the first decoder 4244 in response to an M-bit digital signal and a value of 1+the M-bit digital signal. The second voltage divider 4242b includes 2^{N} resistors connected in series, and receives the output voltages of the second decoder 4245 to generate 2^{N} second level-based gamma reference voltages. The third decoder 4246 selects one of the output voltages of the second voltage divider 4242b in response to an N-bit digital signal, and outputs the selected voltage as the analog signal. L, M and N are natural numbers and may be variable according to the number of bits of the DAC 4250. The number of the decoders can increase or decrease.

Referring to FIG. 6, a method for driving a DAC according to the exemplary embodiment includes: generating a plurality of division voltages by applying a high voltage and a low voltage across a first voltage divider having a plurality of resistors connected in series (S1); selecting first gamma reference voltages among the plurality of division voltages (S2); selecting successive second and third gamma reference voltages among the first gamma reference voltages (S3); generating a plurality of division voltages by applying the second and third gamma reference voltages across a second voltage divider having a plurality of resistors connected in series (S4); selecting a fourth gamma reference voltage among the plurality of division voltages (S5).

Generating the plurality of division voltages by applying the high voltage and the low voltage across the first voltage divider having the plurality of resistors connected in series (S1) includes: preparing the first voltage divider 4242a with a plurality of resistors, i.e., 0^{th} through 255^{th} coarse resistors R₀-R₂₅₅, between a gamma voltage Vgamma and a ground voltage; and generating a plurality of division voltages, i.e., a plurality of first level-based gamma reference voltages, using the gamma voltage Vgamma by connecting input terminals of the first decoder 4244 to the gamma voltage Vgamma, the ground voltage, and among the 0^{th} through 255^{th} coarse resistors R₀-R₂₅₅.

Selecting the first gamma reference voltages among the plurality of division voltages (S2) includes selecting the first gamma reference voltages by the MSB of the pixel data among the first level-based gamma reference voltages. At this point, the plurality of coarse resistors included in the first voltage divider is divided according to the pixel data inputted to the first decoder 4244.

As illustrated in FIG. 7A, for example, when the pixel data “0000000101” is inputted to the decoder 4247, the MSB \textcircled{1} of the pixel data is 0. Thus, the MSB \textcircled{1}(=0) D1 and an inverted value D1B of the MSB \textcircled{1}(=0) are inputted to the first decoder 4244. Since the MSB \textcircled{1} is 1 digit, i.e., 1 bit, the coarse resistors of the first voltage divider 4242a are divided by 2¹, that is, 0^{th} through 127^{th} coarse resistors R₀-R₁₂₇, and 128^{th} through 255^{th} coarse resistors R₁₂₈-R₂₅₅. In addition, the first decoder 4244 selects the first gamma reference voltages \textcircled{a} corresponding to the 0^{th} through 127^{th} coarse resistors R₀-R₁₂₇ among the first level-based gamma reference voltages by using the inputted values D1 and D1B, and applies the selected voltage to the second decoder 4245, that is, the first full-type decoder 4245a and the second full-type decoder 4245b. Although the MSB \textcircled{1} D1 of the pixel data and its inverted value D1B are inputted to the first decoder 4244, the disclosure is not limited to this exemplary embodiment. Only the MSB \textcircled{1} D1 of the pixel data may be inputted to the first decoder 4244. However, it is preferable that the values D1 and D1B are inputted to the first decoder 4244 so as to reduce the number of transistors of the first decoder 4244. In addition, although the first decoder 4244 has two pixel data input terminals, the disclosure is not limited to this exemplary embodiment. For example, the first decoder 4244 may have only one input terminal by providing a transistor configured to be turned on in response to the value D1 and a transistor configured to be turned on in response to the value D1B.

Selecting the successive second and third gamma reference voltages among the first gamma reference voltages (S3) includes selecting the second and third gamma reference voltages \textcircled{b} corresponding to the pixel data other than the MSB and N-bit LSBs among the first gamma reference voltages.

The first full-type decoder 4245a of the second decoder 4245 receives: D2, D3, D4, D5, D6, D7 and D8, which correspond to the 7-bit pixel data \textcircled{2} “0000001” other than 2-bit LSBs \textcircled{3} and 1-bit MSB \textcircled{1}; and their inverted values D2B, D3B, D4B, D5B, D6B, D7B and D8B. The second full-type decoder 4245b receives: D2, D3, D4, D5, D6, D7 and D8+1 which correspond to a value of “0000010” made by adding 1 to “0000001” inputted to the first full-type decoder 4245a; and their inverted values D2B, D3B, D4B, D5B, D6B, D7B and (D8+1)B. Therefore, as illustrated in FIG. 7B, the first full-type decoder 4245a selects the second gamma reference voltage with respect to the first coarse resistor R₁ corresponding to the second coarse resistor of the first gamma reference voltages with respect to the 0^{th} through 127^{th} coarse resistors R₀-R₁₂₇ selected by the first decoder 4244 according to the input pixel data, and applies the selected second gamma reference voltage to one terminal of the second voltage divider 4242b. In addition, the second full-type decoder 4245b selects the third gamma reference voltage with respect to the second coarse resistor R₂ corresponding to the third coarse resistor of the first gamma reference voltages with respect to the 0^{th} through 127^{th} coarse resistors R₀-R₁₂₇ selected by the first decoder 4244 according to the input pixel data, and applies the selected third gamma reference voltage to another terminal of the second voltage divider 4242b.

Generating the plurality of division voltages by applying the second and third gamma reference voltages across the second voltage divider with the plurality of resistors connected in series (S4) includes: preparing the second voltage divider 4242b with a plurality of resistors, i.e., 0^{th} through 4^{th} fine resistors r₀-r₄, between the second gamma reference voltage and the third gamma reference voltage; and generating a plurality of division voltages, i.e., a plurality of second level-based gamma reference voltages, using the second and third gamma reference voltages by connecting input terminals of the third decoder 4246 among the second and third gamma voltages and the 0^{th} through 4^{th} fine resistors r₀-r₄.

As illustrated in FIG. 7C, the second voltage divider 4242b generates the second level-based gamma reference voltages, including the 0^{th} through 3^{rd} gray scales, according to the second and third gamma reference voltages applied from the second decoder 4245.

Selecting the fourth gamma reference voltage among the plurality of division voltages (S5) includes selecting the fourth gamma reference voltage corresponding to N bits of the pixel data among the second level-based gamma reference voltages divided into the 0^{th} through 3^{rd} gray scales.

Referring to FIG. 7C, the third decoder 4246 receives D9 and D10 corresponding to 2-bit LSBs “01” of the pixel data “0000000101”, and their inverted values D9B and D10B. Then, the third decoder 4246 generates a voltage value of the first fine resistor r₁ corresponding to 2/4 of the first coarse resistor R₁ and the second coarse resistor R₂ among the second level-based gamma reference voltages, as the final fourth gamma reference voltage \textcircled{c}, and applies the fourth gamma reference voltage \textcircled{c} to the buffer 4260. The fourth gamma reference voltage \textcircled{c} outputted from the buffer 4260, that is, the gray-scale voltages, are applied to the data lines DL1-DLm of the LCD panel. The tilt angles of the liquid crystals in the LCD panel are changed according to the applied gray-scale voltages and thus the gray scales of the pixels are determined.

As described above, since the source driver divides the decoder of the DAC 4250 into three parts, the number of transistors can be reduced compared when using two decoders. For example, when the conventional 8-bit decoder includes about 2,048 transistors, the decoder in accordance with the exemplary embodiment can implement the 8-bit decoder by using the 1-bit decoder having about 256 transistors and the 7-bit decoder having about 512 transistors. In this case, the 8-bit decoder can be implemented with about 768 transistors. Therefore, the decoder in accordance with the exemplary embodiment has the same performance as the related art but can be scaled down by the reduction of the number of the transistors. Further, the sizes of the source driver and display device having the DAC 4250 can be reduced.

In accordance with the exemplary embodiments, since the decoder of the DAC is divided into a plurality of decoders, the number of transistors of each decoder is reduced and the size of the decoder is reduced. Therefore, the DAC with the reduced size, the driving method thereof, the source driver having the same, and the display device having the source driver can be provided.

Moreover, by applying the DAC with the reduced size, the sizes of the source driver with the DAC and the display device with the source driver can also be reduced.

Although the DAC, the method for driving the DAC, the source driver with the DAC, and the display device with the source driver have been described with reference to the specific embodiments, they are not limited thereto. Therefore, it will be readily understood by those skilled in the art that various modifications and changes can be made thereto without departing from the spirit and scope of the present invention defined by the appended claims.

For example, although the LCD has been described in the above exemplary embodiments, the disclosure is not limited thereto. The subject matter described herein can be applied to any type of the display device with the source driver, and can be applied to active-driving organic light emitting diodes (OLEDs) and plasma display panels (PDPs).

What is claimed is:

1. A digital-to-analog converter, comprising:
a first voltage divider including a plurality of resistors;
a first decoder configured to receive first division voltages from the first voltage divider to output a plurality of first gamma reference voltages;
a second decoder configured to output two successive voltages among the first gamma reference voltages as second and third gamma reference voltages;
a second voltage divider including a plurality of resistors to divide the second and third gamma reference voltages into a plurality of second division voltages; and
a third decoder configured to receive the second division voltages from the second voltage divider to output a fourth gamma reference voltage.

2. The digital-to-analog converter of claim 1, wherein the first voltage divider comprises 2^{L+M} coarse resistors, and the second voltage divider comprises 2^{N} fine resistors, where L, M and N are natural numbers.

3. The digital-to-analog converter of claim 2, wherein the first decoder is configured to receive (L+M+N)-bit pixel data.

4. The digital-to-analog converter of claim 3, wherein the first decoder comprises an L-bit decoder, the second decoder comprises an M-bit decoder, and the third decoder comprises an N-bit decoder.

5. The digital-to-analog converter of claim 4, wherein the second decoder comprises two M-bit decoders, and a difference between least significant bits (LSB) of pixel data inputted to the two M-bit decoders is 1.

6. The digital-to-analog converter of claim 1, wherein the digital-to-analog converter is an (L+M+N)-bit converter.

7. The digital-to-analog converter of claim 4, wherein the value of L is 1, the value of M is 7, and the value of N is 2.

8. A source driver for generating and outputting a gamma reference voltage by using a reference voltage, the source driver comprising:
a first voltage divider with a plurality of resistors;
a second voltage divider with a plurality of resistors; and
first to third decoders configured to select division voltages outputted from the first and the second voltage dividers.

9. The source driver of claim 8, wherein the first decoder selects a first gamma reference voltage based on a division voltage outputted from the first voltage divider;
a second decoder selects second and third gamma reference voltages based on the first gamma reference voltage; and
a third decoder receives the second and third gamma reference voltages and selects a fourth gamma reference voltage based on a division voltage outputted from the second voltage divider.

10. The source driver of claim 8, wherein the first voltage divider comprises 2^{L+M} coarse resistors, and the second voltage divider comprises 2^{N} fine resistors, where L, M and N are natural numbers.

11. The source driver of claim 10, wherein the first decoder is configured to select one of 2^{L} division voltages and output the selected division voltage as a first gamma reference voltage.

12. The source driver of claim 11, wherein the second decoder is configured to output two successive voltages of the first gamma reference voltages as second and third gamma reference voltages.

13. The source driver of claim 12, wherein the third decoder is configured to receive 2^{N} division voltages from the second voltage divider and output a fourth gamma reference voltage.

14. A display device, comprising:
a display panel configured to display an image; and
a source driver configured to generate and output a gamma reference voltage by using a reference voltage, the source driver comprising:
a first voltage divider with a plurality of resistors;
a second voltage divider with a plurality of resistors; and
first, second, and third decoders configured to select division voltages outputted from the first and the second voltage dividers.

15. The display device of claim 14, wherein the first decoder selects a first gamma reference voltage based on a division voltage outputted from the first voltage divider;
the second decoder selects second and third gamma reference voltages based on the first gamma reference voltage; and
the third decoder receives the second and third gamma reference voltages and selects a fourth gamma reference voltage based on a division voltage outputted from the second voltage divider.

16. A method for driving a digital-to-analog converter, comprising:
generating a plurality of division voltages;
selecting first gamma reference voltages among the plurality of division voltages;
selecting successive second and third gamma reference voltages among the first gamma reference voltages;
generating a plurality of division voltages based on the second and third gamma reference voltages; and
selecting a fourth gamma reference voltage among the plurality of division voltages.

17. The method of claim 16, wherein selecting the first gamma reference voltages among the plurality of division voltages comprises:
selecting the first gamma reference according to L-bit pixel data of the (L+M+N)-bit pixel data.

18. The method of claim 17, wherein selecting the first gamma reference voltages among the plurality of division voltages comprises:
selecting one of 2^{L} division voltages divided by L-bit pixel data to output the first gamma reference voltages.

19. The method of claim 16, wherein selecting the successive second and third gamma reference voltages among the first gamma reference voltages comprises:
selecting the second gamma reference voltage by using M-bit pixel data of the (L+M+N)-bit pixel data;
adding 1 to the M-bit pixel data of the (L+M+N)-bit pixel data; and
selecting the third gamma reference voltage by using the value of 1+the M-bit pixel data.

20. The method of claim 16, wherein selecting the fourth gamma reference voltage among the plurality of division voltages comprises:
selecting the fourth gamma reference voltage by using N-bit pixel data of the (L+M+N)-bit pixel data.
